(19) United States
(12) Patent Application Publication
(10) Pub. No.: US 2013/0068274 A1
(43) Pub. Date: Mar. 21, 2013

(54) METHOD FOR PRODUCING A THERMOELECTRIC COMPONENT AND THERMOELECTRIC COMPONENT

(71) Applicants: Joachim Nurnus, Neuenburg (DE); Harald Boettner, Freiburg (DE); Axel Schubert, Muenchen (DE)

(72) Inventors: Joachim Nurnus, Neuenburg (DE); Harald Boettner, Freiburg (DE); Axel Schubert, Muenchen (DE)

(73) Assignee: MICROPELT GMBH, Freiburg (DE)

(21) Appl. No.: 13/498,863

(22) PCT Filed: Sep. 29, 2010
(86) PCT No.: PCT/EP10/64433

§ 371 Date: Jun. 16, 2012

(30) Foreign Application Priority Data
Sep. 30, 2009 (DE) 10 2009 045 208.7

(51) Int. Cl. H01L 35/34; H01L 35/16

(52) U.S. Cl. 136/238; 438/54; 257/E31.026; 136/201

(57) ABSTRACT

A method for manufacturing a thermoelectric component is provided. The method comprises the following steps: producing a plurality of first layers of a first thermoelectric material, and producing a plurality of second layers of a second thermoelectric material, such that the first layers are arranged in alternation with the second layers. Producing the first and/or the second thermoelectric layers each comprises producing at least one first initial layer and at least one second initial layer.

### CROSS-REFERENCE TO A RELATED APPLICATION

This application is a National Phase patent application of International Patent Application Number PCT/EP2011/039240, filed on Sep. 29, 2010, which claims priority of German Patent Application Number 10 2009 045 208.7, filed on Sep. 30, 2009.

### BACKGROUND

This invention relates to methods for manufacturing a thermoelectric component and to a thermoelectric component.

Thermoelectric components which generate an electric voltage under the influence of a temperature gradient are known from the prior art. In particular, U.S. Pat. No. 6,300,150 describes a thermoelectric component which has a layered structure.

### SUMMARY

The problem underlying the invention consists in indicating a method with which an efficient thermoelectric component can be manufactured in the simplest way possible. Furthermore, a most efficient and nevertheless easily manufacturable thermoelectric component should be provided.

According to an exemplary embodiment of the invention a method for manufacturing a thermoelectric component is provided, with the following steps:
producing a plurality of first layers of a first thermoelectric material, and
producing a plurality of second layers of a second thermoelectric material, such that
the first layers are arranged in alternation with the second layers, wherein
producing the first layers and/or the second layers each comprises producing at least one first initial layer (precursor layer) and at least one second initial layer.

In particular, the first and the second thermoelectric layers can be arranged and formed such that they form a superlattice. Such superlattices are characterized for example by a relatively high electric, but low thermal conductivity as compared to non-layered materials. The relatively low thermal conductivity of such superlattices made of thermoelectric layers can increase the thermoelectric efficiency of the thermoelectric component. In one variant of the invention, the thermoelectric component includes a superlattice with a total thickness of at least 5 μm, e.g. at least 18 μm, in particular several 10 μm. The thicknesses of the first and second thermoelectric layers for example each lie in the range of a few nm (e.g. at least about 10 nm).

The initial layers each have a thickness of at least a few atomic layers, e.g. in the range between 1 nm and 10 nm, for example at least 3 nm, at least 5 nm or at least 10 nm.

It should be noted that a “thermoelectric material” is a material which has a high thermoelectric coefficient as compared to other materials, i.e. can produce a comparatively high temperature difference relative to a voltage applied to the material or, vice versa, produces a comparatively high voltage (current) at a given temperature difference. For example, a thermoelectric material can have a thermoelectric coefficient (Seebeck coefficient) of more than 50 μV/K. Examples of such thermoelectric materials will be discussed below.

Producing the first and the second thermoelectric layer in particular is effected such that an intermediate layer each is obtained between the same, which includes the first and the second thermoelectric material. Such intermediate layer is obtained, for example, when the first and second thermoelectric layers are formed by tempering (i.e. by a heat treatment) of the first and second initial layers.

To achieve an easier manufacturability of the component, it is accepted that the phase boundaries between the first and second thermoelectric layers do not extend in a steplike manner. Rather, a transition region is obtained with the intermediate layer, in which the concentration of the first thermoelectric material substantially constantly decreases from a first to an adjacent second layer or the concentration of the second thermoelectric material substantially constantly decreases towards an adjacent first layer. Thus, soft transitions exist between the first and the second layers, so that reference can also be made to a “soft” superlattice.

Thus, in accordance with this variant of the invention, the diffusion between adjacent thermoelectric layers is not inhibited, but accepted, as this simplifies the manufacture of a thermoelectric superlattice and nevertheless leads to a superlattice structure which has a lower thermal conductivity than a homogeneous mixture of both layers and thus has a high coefficient of performance (usually referred to as “COP”, wherein COP takes account of the thermal conductivity, the Seebeck coefficient and the electrical conductivity).

By tempering, the materials of the first and the second initial layers are bonded, so that the desired (first and second) thermoelectric layers are obtained. The stoichiometry of the first and second layers can be adjusted for example via the thicknesses of the respective initial layers. During the tempering step, the initial layers in particular are exposed to a temperature which is higher than the temperature when producing the initial layers; for example to a temperature between 100° C. and 500° C.

For producing a plurality of first and second thermoelectric layers, at least two initial layers per thermoelectric layer to be produced correspondingly are formed, so that correspondingly a plurality of initial layers is arranged periodically.

In a further exemplary aspect of the method according to the invention, the material of the first initial layer is an element of the sixth main group of the periodic table and the material of the second initial layer is an element of the fifth main group of the periodic table. For example, for producing the first layers bismuth or tellurium is used as material for the initial layers, wherein—for example after a tempering step—thermoelectric layers of bismuth telluride are obtained.

For producing the second thermoelectric layers, a first initial layer of antimony or of antimony and bismuth and a second initial layer again of telluride can be chosen, in order to for example after tempering produce second thermoelectric layers of antimony telluride (or antimony bismuth telluride).

It should be appreciated that the invention is not limited to a structure or a manufacturing method, which only includes two different thermoelectric materials. There can also be provided more than two layers of a different thermoelectric material.

The first and the second initial layer for example are produced by sputtering. Sputtering in particular is effected such that the substrate on which the first and the second initial layers are deposited is alternately moved through the deposition region of a first sputtering target and the deposition region of a second sputtering target. The “deposition region” is a space region in which a deposition of the material sputtered from a sputtering target on the substrate is possible.

In particular, the first sputtering target includes the material of the first initial layer and the second sputtering target includes the material of the second initial layer. It is of course possible that more than two targets are used. For example, the targets are bismuth, tellurium, antimony or selenium targets (stationarily arranged in a sputtering plant).

Furthermore, it is conceivable that the substrate (in the sputtering chamber) is rotated such that it alternately moves through the deposition region of a first sputtering target and the deposition region of a second sputtering target. In particular, the thickness of the initial layers can be adjusted via the rotational speed of the substrate and/or the sputtering rate.

It should be noted that the invention is of course not limited to the production of the initial layers by sputtering, but other deposition methods can also be used, e.g. vapor deposition or MBE (molecular beam epitaxy). As mentioned above, tempering of the initial layers can be effected after producing the initial layers, i.e. after the sputtering process. This tempering in particular is carried out in a separate tempering plant.

In another exemplary aspect, the invention relates to a method for manufacturing a thermoelectric component, with the following steps:
producing a plurality of first layers of a first thermoelectric material;
producing a plurality of second layers of a second thermoelectric material, such that
the first layers are arranged in alternation with the second layers, and
an intermediate layer is obtained between the first and the second layers, which includes the first and the second material, wherein
the first and/or the second thermoelectric material is a compound of at least one element of the fifth with at least one element of the sixth main group of the periodic table or a compound of at least one element of the fourth with at least one element of the sixth main group of the periodic table.

Accordingly, it is not absolutely necessary to use initial layers for producing the first and the second thermoelectric layers. Rather, the thermoelectric layers also can be produced directly. For example, the first and the second thermoelectric layers are produced by sputtering, wherein in particular mixed targets are used (see below).

It is possible that the first and the second thermoelectric layer are produced on a substrate by alternately moving (e.g. rotating) the substrate through the deposition region of a first sputtering target and the deposition region of a second sputtering target, as already explained above with respect to the first aspect of the invention.

In particular, the first and the second sputtering target each are a mixed target, wherein e.g. the first sputtering target includes a first compound of at least one element of the fifth with at least one element of the sixth main group of the periodic table and the second sputtering target includes a second compound of this type, which is different from the first compound. In particular, the first compound is bismuth telluride and the second compound is antimony telluride. The targets in particular are optimized such (e.g. composition) that in combination with the used sputtering conditions (substrate temperature, sputtering rate, etc.) a layer with the desired properties (e.g. composition) can be produced.

It is also conceivable that the first and the second thermoelectric material are identical, e.g. each consist of bismuth telluride. There can be provided a barrier layer (X) between adjacent thermoelectric layers, e.g. of Ni, Cr, NiCr, Ti, Pt, TiPt, so that a layer sequence Bi₂Te₃-X—Bi₂Te₃ would be produced. For example, Bi₂Te₃—X—(Bi,Sb)₂(Te,Se)₃ would also be conceivable.

Producing the first and the second thermoelectric layers is effected e.g. at a temperature between 20° C. and 300° C. In addition, the first and the second thermoelectric layers can be subjected to a tempering step, after they have been produced, wherein they are heated in particular to up to 500° C., e.g. to at least 100° C., at least 200° C. or at least 300° C.

In accordance with another exemplary variant of the invention, the first thermoelectric material is silicon and the thermoelectric second material is germanium, wherein e.g. after producing the layers there is also carried out a tempering step, e.g. with a temperature of at least 500° C.

The invention also comprises a thermoelectric component, with
a plurality of first layers of a first thermoelectric material;
a plurality of second layers of a second thermoelectric material, wherein the first layers are arranged in alternation with the second layers.

Between the first and the second layers, an intermediate layer each is formed, which includes the first and the second thermoelectric material.

The thermoelectric component according to an exemplary embodiment of the invention thus has a periodic layered structure with at least two different thermoelectric materials. The intermediate layer (transition layer) formed between the thermoelectrically active layers is obtained e.g. by diffusion of the first thermoelectric material to an adjoining (second) layer and vice versa of the second material to an adjoining (first) layer. For example, manufacturing the thermoelectric component is effected by using a method as described above.

The thickness of the intermediate layer is, as mentioned, e.g. at least 3 nm or at least 5 nm. The concentration of the first and the second thermoelectric material in the intermediate layer will vary depending on the location, wherein as boundaries of the intermediate layer (which define the thickness thereof) in particular those locations between the first and the second layer are regarded, at which the concentrations of the first and the second thermoelectric material fall below one fourth of the corresponding concentration in the first and in the second layer, respectively.

In one exemplary variant of the invention, the first and/or the second thermoelectric material is a compound of at least one element of the fifth with at least one element of the sixth main group of the periodic table. For example, the first thermoelectric material can be bismuth telluride or bismuth selenide and the second thermoelectric material can be antimony telluride or antimony selenide. Other (e.g. ternary or quaternary) compositions are of course also conceivable, such as Bi₂Te₃/(Bi,Sb)₂(Te,Se)₃ or Sb₂Te₃/(Bi,Sb)₂Te₃.

In addition, it should be noted that the wording according to which the intermediate layer “includes the first and the second thermoelectric material” of course also covers the case that the first and the second thermoelectric material are present in the intermediate layer as (e.g. ternary or quaternary) mixed compound. For example, the thermoelectric layers can be formed of bismuth telluride or antimony telluride and the intermediate layer can be formed of bismuth antimony telluride.

In another exemplary variant of the invention, the first and/or the second material is a compound of at least one element of the fourth with at least one element of the sixth main group of the periodic table, e.g. lead telluride or lead selenide.

In a further exemplary embodiment, the first material is silicon and the second material is germanium.

### BRIEF DESCRIPTION OF THE DRAWINGS

The invention will subsequently be explained in detail by means of an exemplary embodiment with reference to the Figures:

FIGS. 1A to 1C show manufacturing steps in one variant of the method according to the invention.

### DETAILED DESCRIPTION

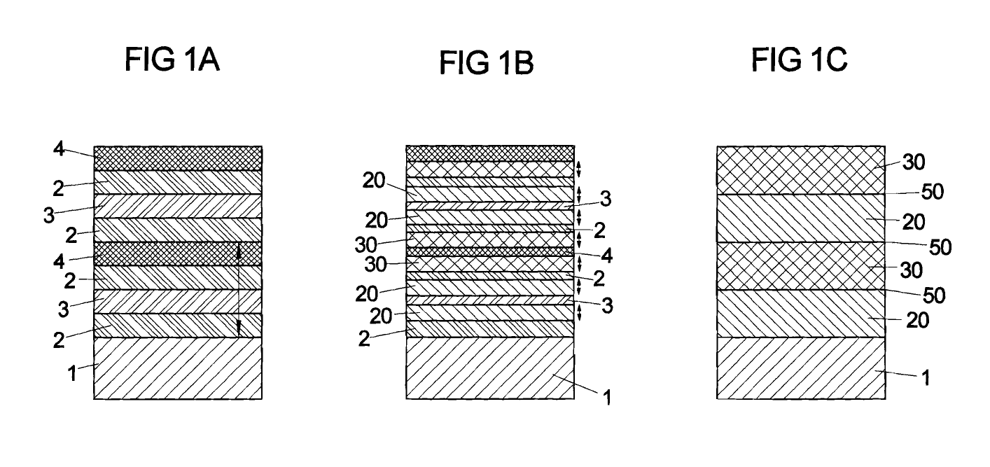

FIG. 1A shows a substrate 1 on which a plurality of initial layers 2 to 4 are arranged periodically. The initial layers serve for producing a thermoelectric superlattice. In particular, first initial layers 2 and second initial layers 3 adjacent to the same are provided, which are provided for forming first layers of a first thermoelectric material. In the illustrated example, the first initial layers 2 are formed of tellurium and the second initial layers 3 are formed of antimony. It should be appreciated that other materials can also be used for these initial layers, e.g. selenium instead of tellurium.

Some of the first initial layers 2 also serve for forming second thermoelectric layers, as they each adjoin a further (second) initial layer 4 with their side facing away from the adjacent second initial layer 3. In the present example, the initial layer 4 is formed of bismuth.

After producing the layered structure shown in FIG. 1A, which is effected e.g. by vapor deposition or sputtering, the layered structure is subjected to one or more tempering steps. Starting at the interfaces between the initial layers—there is formed a compound 20, 30 of the material (element) of the first initial layers 2 with the material of the second initial layers 3 and 4, respectively. The formation of the compound proceeds from the interfaces of adjacent initial layers into the initial layers, since the material (the elements) of the initial layers diffuses through compounds formed already. This occurs until the elementary materials of the initial layers are reacted and thus the first and second thermoelectric layers are produced. This procedure is shown in FIG. 1B. In the illustrated example, there are formed first thermoelectric layers of antimony telluride and second layers of bismuth telluride.

Via the ratio of the layer thicknesses of the second initial layers 3, 4 to the thickness of the first initial layer 2, i.e. via the ratio of the thickness of the antimony or bismuth layers to the thickness of the tellurium layers, the stoichiometry of the first and second thermoelectric material layers to be formed is defined. In the present example, the layer thicknesses are chosen such that the first thermoelectric layers are formed of Sb₂Te₃ and the second thermoelectric layers are formed of Bi₂Te₃.

After completion of the reaction, i.e. after termination of tempering, a layered structure has been formed, which includes a plurality of first layers of a first thermoelectric material 20 (Sb₂Te₃) and a plurality of second layers of a second thermoelectric material 30 (Bi₂Te₃), which are arranged in alternation; cf. FIG. 1C. As in the tempering process (FIG. 1B) there also occurs an oppositely directed diffusion of the elements of the second initial layers 3, 4 (antimony or bismuth), intermediate layers 50, which include (Bi,Sb)₂Te₃, i.e. both Sb₂Te₃ and Bi₂Te₃, are formed between the first and second thermoelectric layers of the materials 20, 30.

In this exemplary embodiment, both the first and second thermoelectric layers and at the same time the intermediate layers thus are produced by tempering.

The layered structure shown in FIG. 1C thus includes no abrupt phase transitions between the first thermoelectric layers and the second thermoelectric layers, but a (soft) transition zone each, in which the amount of the first material 20 continuously decreases from a first layer to an adjoining second layer and the amount of the second material 30 continuously decreases from a second layer to an adjoining first layer.

The method, in particular the formation of the intermediate layers between the first and the second thermoelectric layers, also can be carried out with other initial layers, e.g. with selenium layers instead of the tellurium layers.

1. A method for manufacturing a thermoelectric component, with the following steps:
producing a plurality of first layers of a first thermoelectric material, and
producing a plurality of second layers of a second thermoelectric material, such that the first layers are arranged in alternation with the second layers, wherein
producing the first and/or the second thermoelectric layers each comprises producing at least one first initial layer and at least one second initial layer.

2. The method according to claim 1, wherein when producing the first and/or the second thermoelectric layers an intermediate layer is formed between the first and the second thermoelectric layers, which includes the first and the second material.

3. The method according to claim 1, wherein producing the first and the second initial layer is effected at a temperature between 50° C. and 250° C.

4. The method according to claim 1, wherein producing the first and/or the second thermoelectric layer comprises tempering of the first and the second initial layer, wherein the initial layers in particular are exposed to a temperature of at least 100° C., in particular at least 200° C., or to a temperature between 100° C. and 500° C., in particular between 200° C. and 500° C.

5. The method according to claim 4, wherein tempering is effected such that at the same time the intermediate layer (50) between the first and the second thermoelectric layers is produced.

6. The method according to claim 1, wherein the first initial layer is formed of at least one element of the sixth main group of the periodic table and the second initial layer is formed of at least one element of the fifth main group of the periodic table.

7. The method according to claim 6, for producing one of the first layers the element of the fifth main group is bismuth, the element of the sixth main group is tellurium, and the first layer is formed of bismuth telluride.

8. The method according to claim 6, wherein for producing one of the second layers the element of the fifth main group is antimony or antimony and bismuth, the element of the sixth main group is tellurium, and the first layer is formed of antimony telluride or antimony bismuth telluride.

9. The method according to claim 1, wherein the first and the second initial layer are produced by sputtering, vapor deposition or molecular beam epitaxy.

10. The method according to claim 9, wherein the first and the second initial layer are produced on a substrate by alternately moving the substrate through the deposition region of a first sputtering target and the deposition region of a second sputtering target,

11. The method according to claim 10, wherein the first sputtering target includes the material of the first initial layer and the second sputtering target includes the material of the second initial layer.

12. The method according to claim 10, wherein the substrate is rotated such that it alternately moves through the deposition region of a first sputtering target and the deposition region of a second sputtering target.

13. (canceled)

14. A method for manufacturing a thermoelectric component, in particular according to claim 1, with the following steps:
producing a plurality of first layers of a first thermoelectric material;
producing a plurality of second layers of a second thermoelectric material, such that
the first layers are arranged in alternation with the second layers, and
an intermediate layer is obtained between the first and the second layers, which includes the first and the second thermoelectric material, wherein
the first and/or the second thermoelectric material is a compound of at least one element of the fifth with at least one element of the sixth main group of the periodic table.

15. The method according to claim 14, wherein the first and the second thermoelectric layers are produced by sputtering.

16. The method according to claim 15, wherein the first and the second thermoelectric layer are produced on a substrate by alternately moving the substrate through the deposition region of a first sputtering target and the deposition region of a second sputtering target.

17. (canceled)

18. (canceled)

19. (canceled)

20. (canceled)

21. (canceled)

22. A thermoelectric component, comprising
a plurality of first layers of a first thermoelectric material;
a plurality of second layers of a second thermoelectric material, wherein
the first layers are arranged in alternation with the second layers, and
between the first and the second layers, an intermediate layer each is formed, which includes the first and the second thermoelectric material, and
the first and/or the second thermoelectric material is a compound of at least one element of the fifth with at least one element of the sixth main group of the periodic table.

23. (canceled)

24. (canceled)

25. (canceled)

26. The thermoelectric component according to claim 22, wherein the first material is bismuth telluride or bismuth selenide and the second material is antimony telluride or antimony bismuth telluride.

27. (canceled)

28. (canceled)

29. (canceled)

30. The thermoelectric component according to claim 22, wherein the first and second layers each adjoin each other such that a diffusion of the first material from a first layer to an adjoining second layer and vice versa a diffusion of the second material from a second layer to an adjoining first layer can be effected.

31. The thermoelectric component according to claim 22, wherein the first and the second layers form a layer package with a thickness of approximately 5-20 μm.

32. A method for manufacturing a thermoelectric component, in particular according to claim 1, with the following steps:
producing a plurality of first layers of a first thermoelectric material;
producing a plurality of second layers of a second thermoelectric material, such that
the first layers are arranged in alternation with the second layers, and
an intermediate layer is obtained between the first and the second layers, which includes the first and the second thermoelectric material, wherein
the first and/or the second thermoelectric material is a compound of at least one element of the fifth with at least one element of the sixth main group of the periodic table or a compound of at least one element of the fourth with at least one element of the sixth main group of the periodic table, wherein
the first and the second thermoelectric layers are produced by sputtering in such a way that the first and the second thermoelectric layer are produced on a substrate by alternately moving the substrate through the deposition region of a first sputtering target and the deposition region of a second sputtering target.
